(19) United States
(12) Patent Application Publication
(10) Pub. No.: US 2010/0232233 A1
(43) Pub. Date: Sep. 16, 2010

(54) NONVOLATILE SEMICONDUCTOR MEMORY DEVICE

(76) Inventors: Takuya FUTATSUYAMA, Yokohama-shi (JP); Makoto Iwai, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/721,689

(22) Filed: Mar. 11, 2010

(30) Foreign Application Priority Data
Mar. 13, 2009 (JP) 2009-062007

(51) Int. Cl. G11C 16/06; G11C 16/04

(52) U.S. Cl. 365/185.23; 365/185.18

(57) ABSTRACT

A nonvolatile semiconductor memory device in which a negative-threshold cell read operation is performed by biasing a source line and well line to a positive voltage includes a first drive circuit that sets at least unselected word line in a floating state at a negative-threshold cell read time.

### CROSS-REFERENCE TO RELATED APPLICATIONS

This application is based upon and claims the benefit of priority from prior Japanese Patent Application No. 2009-062007, filed Mar. 13, 2009, the entire contents of which are incorporated herein by reference.

### BACKGROUND OF THE INVENTION

1. Field of the Invention

This invention relates to a nonvolatile semiconductor memory device, for example, a NAND flash memory capable of reading data from a cell with a negative threshold value.

2. Description of the Related Art

A NAND flash memory is known as a nonvolatile semiconductor memory device in which data can be electrically rewritten (written and erased) and that is suitable for high integration density and large memory capacity. In the NAND flash memory, an attempt is made to read data from a cell with a negative threshold value (i.e., negative potential read or negative level sense). In the NAND flash memory capable of performing a negative-threshold cell read operation, a source line and well line are biased to a positive voltage (for example, 1 V) at the data read time (for example, see U.S. Patent Application Publication No. 2006/0133150 A1). That is, a voltage of each selected word line(s) (WL) is set to a value approximately equal to 0 V (a voltage of each unselected word line(s) is set to approximately 6 V) by writing multivalued data (for example, not less than eight values/not less than three bits) in a NAND flash memory that may contain negative-threshold cells. In this state, the read and verify operations for the negative-threshold cell are performed by biasing the source line and well line to a positive voltage.

Thus, it is studied to stably perform a negative-threshold cell read operation by biasing the source line and well line to a positive voltage at the read time in a NAND flash memory. Particularly, recently, it is desired to increase the operation speeds of the negative-threshold cell read and write operations.

### BRIEF SUMMARY OF THE INVENTION

According to an aspect of the present invention, there is provided a nonvolatile semiconductor memory device in which a negative-threshold cell read operation is performed by biasing a source line and well line to a positive voltage, comprising: a first drive circuit that sets at least unselected word line in a floating state at a negative-threshold cell read time.

According to an aspect of the present invention, there is provided a nonvolatile semiconductor memory device comprising: a memory cell array including cell strings, each cell string being configured by a serial connection of cell transistors and select transistors, the cell transistors configured to store data nonvolatily according to a threshold voltage of corresponding one cell transistor and configured to have a negative threshold voltage; a driver that biases a source line and well line to a positive voltage; word lines connected to the cell transistors respectively, and a drive circuit configured to apply first and second voltages used to read data from the cell transistors to one or more selected word lines and one or more unselected word lines among the word lines, the first and second voltages being set to voltages obtained by adding the positive voltage to the first and second voltages for reading data from the cell transistor having the negative threshold voltage, and the drive circuit setting the one or more unselected word lines in a floating state when data is read from one or more of the cell transistors having the negative threshold voltage.

### BRIEF DESCRIPTION OF THE SEVERAL VIEWS OF THE DRAWING

FIG. 1 is a block diagram showing a configuration example of a nonvolatile semiconductor memory device (NAND flash memory) according to an embodiment 1 of this invention.

FIG. 2 shows a circuit configuration example of a NAND cell string in a memory cell array of the NAND flash memory.

FIG. 3 shows a circuit configuration example of a CG driver of the NAND flash memory.

FIG. 4 shows a circuit configuration example of an SGD driver of the NAND flash memory.

FIG. 5 shows a circuit configuration example of an SGS driver of the NAND flash memory.

FIG. 6 shows circuit configuration examples of a VEST driver, VCGSEL driver and VRDEC driver of the NAND flash memory.

FIG. 7 shows a configuration n example of a VSG bias circuit of the NAND flash memory.

FIG. 8 is a timing chart for illustrating a negative-threshold cell read operation in an example in which only unselected word line(s) are set in a floating state.

FIG. 9 is a circuit diagram showing an example in which the CG driver is configured by use of a local pump circuit L/S1-1.

FIG. 10 is a timing chart for illustrating the operation of the CG driver at the negative-threshold cell read time.

FIG. 11 shows the circuit configuration of the local pump circuit L/S1-1.

FIG. 12 is a timing chart for illustrating the operation of the local pump circuit L/S1-1.

FIG. 13 is a circuit diagram showing an example in which a CG driver is configured by using a local pump circuit L/S1-2 according to an embodiment 2 of this invention.

FIG. 14 is a timing chart for illustrating the operation of the CG driver at the negative-threshold cell read time.

FIG. 15 shows the circuit configuration of the local pump circuit L/S1-2.

FIG. 16 is a timing chart for illustrating the operation of the local pump circuit L/S1-2.

FIG. 17 is a timing chart for illustrating a negative-threshold cell read operation in an example in which word lines are all set in a floating state.

FIG. 18 is a timing chart for illustrating a negative-threshold cell read operation in an example in which all word lines and one of select signal lines are set in a floating state according to an embodiment 3 of this invention.

FIG. 19 is circuit diagram showing an example in which an SGS driver is configured by using a level shifter L/S2.

FIG. 20 is a timing chart for illustrating the operation of the SGS driver at the negative-threshold cell read time.

FIG. 21 shows a circuit configuration example of the level shifter L/S2.

FIG. 22 is a timing chart for illustrating the operation of the level shifter L/S2.

FIG. 23 is a timing chart for illustrating a negative-threshold cell read operation in an example in which all word lines and select signal lines are set in a floating state.

FIG. 24 is a timing chart for illustrating an example in which only unselected word line(s) are set in a floating state at the negative-threshold cell read time with changed voltage rise timings.

FIG. 25 is a timing chart for illustrating an example in which word lines are all set in a floating state at the negative-threshold cell read time with changed voltage rise timings.

FIG. 26 is a timing chart for illustrating an example in which all word lines and one of select signal lines are set in a floating state at the negative-threshold cell read time with changed voltage rise timings.

FIG. 27 is a timing chart for illustrating an example in which all word lines and select signal lines are set in a floating state at the negative-threshold cell read time with changed voltage rise timings.

### DETAILED DESCRIPTION OF THE INVENTION

Now, embodiments of this invention will be explained in detail below with reference to the accompanying drawings. In this case, it should be noted that the drawings are schematic ones and the dimensions and ratios shown in the drawings may be different from the actual ones. Further, drawings may include portions whose relative positions and/or sizes are different in different drawings. Particularly, several embodiments described below are directed to a device and a method for embodying the technical concept of the present invention and the technical concept of this invention is not specified by the shape, structure or arrangement of components. Various changes can be made to the technical concept of the present invention without departing from the scope thereof.

### Embodiment 1

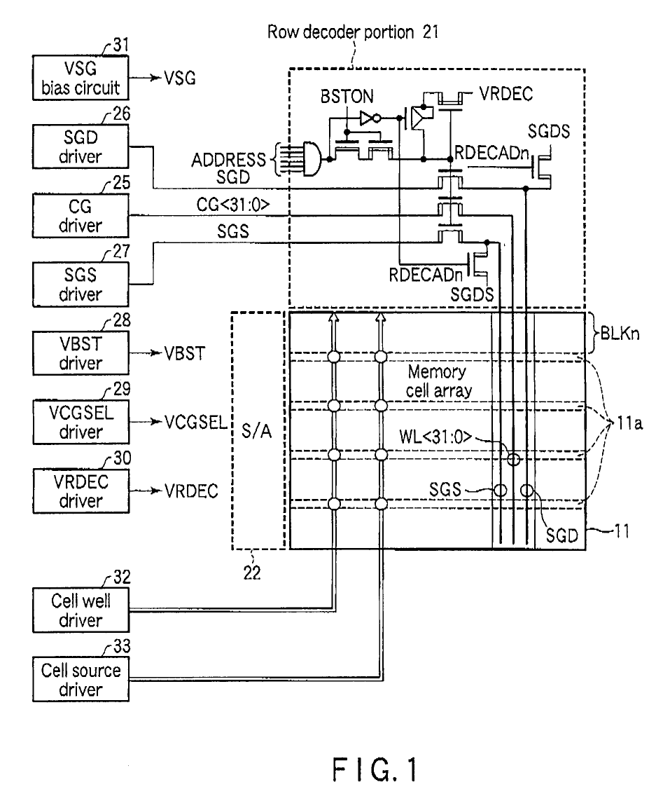

FIG. 1 shows a basic configuration of a nonvolatile semiconductor memory device according to an embodiment 1 of this invention. In this embodiment, a NAND flash memory comprising memory cells each configured by a metal oxide semiconductor (MOS) transistor with a double (laminated) gate structure is explained as an example. Further, the following description relates to an example of an all bit-lines select sense scheme.

As shown in FIG. 1, a memory chip comprises a core portion and peripheral circuit portion. The core portion comprises a memory cell array 11, row decoder portion 21, sense amplifier portion 22 and the like. For example, the peripheral circuit portion comprises a CG driver 25, SGD driver 26, SGS driver 27, VBST driver 28, VCGSEL driver 29, VRDEC driver 30 and VSG bias circuit 31, which are used to control the row decoder portion 21. Further, in the peripheral circuit portion, a cell well driver 32 and cell source driver 33 are provided.

In FIG. 1, a column decoder portion, address circuit, high-voltage generation circuit, input/output (I/O) circuit, control circuit and core control drive portion are omitted for convenience.

The memory cell array 11 comprises NAND cells (memory cell transistors) and nonvolatily stores multivalued data (write data) of, for example, not less than eight values or not less than three bits for each cell transistor. The cell transistor becomes a positive- or negative-threshold cell according to a write state (level). The memory cell array 11 will be described in detail later.

The row decoder portion 21 receives a block select signal (ADDRESS) from the address circuit and selects one of blocks BLKn of the memory cell array 11 that corresponds to the block select signal. Then, it supplies an adequate voltage corresponding to the operation to word lines WL (WL<31:0>) of the selected block BLKn. Further, the row decoder portion 21 supplies adequate voltages corresponding to the operation to select gates (select transistors SGTD, SGTS) of the selected block BLKn via select signal lines SGD, SGS.

The sense amplifier portion 22 comprises sense amplifiers (S/A) and senses the state (held data) of a cell transistor of the selected state (that is hereinafter referred to as a selected cell).

The cell well driver 32 controls a voltage of a cell well line (CPWELL) via a shunt area 11a in the memory cell array 11. The cell well driver 32 biases the voltage of the cell well line CPWELL to a positive voltage (for example, 1 V) at the negative-threshold cell read (negative potential read or negative level read) time.

The cell source driver 33 drives a cell source line (SRC) via the shunt area 11a in the memory cell array 11. The cell source driver 33 biases the voltage of the cell source line SRC to a positive voltage (for example, 1 V) at the negative-threshold cell read time.

The core control drive portion is a driver circuit that controls the core portion of the memory chip and supplies a control signal (control pulse BSTON) corresponding to the operation and an adequate voltage (SGDS) corresponding to the operation to the memory cell array 11, row decoder portion 21 and sense amplifier portion 22.

The column decoder portion controls a connection between a column (sense amplifier S/A) selected from the memory cell array 11 and a data line (not shown) according to a column select signal from the address circuit and transfers read data and write data to and from the input/output circuit from and to the sense amplifier S/A.

The address circuit generates a block select signal and column select signal according to the operation and address information input from the exterior of the memory chip, supplies a block select signal to the row decoder portion 21 and supplies a column select signal to the column decoder portion.

The high-voltage generation circuit contains a charge pump circuit and generates and supplies a voltage corresponding to the operation to the core control drive portion according to an instruction from the control circuit. Further, the high-voltage generation circuit generates voltages VPGM, VPGMH, VUSEL, VCGRV, VREADH and VSGD, for example. Voltage VPGM is a program voltage and is applied to a selected word line at the program (write) operation time.

Voltage VPGMH is a voltage that can be used to transfer voltage VPGM by means of a level shifter. Voltage VUSEL is used as voltage VPASS at the program operation time and as voltage VREAD at the read operation time and verify time. Voltages VPASS and VREAD are both applied to the unselected word line(s) at each corresponding operation time. Voltage VCGRV is applied to a selected word line at the read operation time and verify time. Voltage VREADH is a voltage that can transfer voltage VREAD by means of the level shifter. Voltage VSGD is a voltage of approximately 2.5 V that is applied to select signal line SGD in the SGD driver 26, for example.

The input/output circuit fetches a command, address information and write data input from an I/O pad (not shown) of the memory chip at the program operation time according to an instruction from the control circuit. Then, it respectively outputs the command, address information and write data to the control circuit, address circuit and data line. Further, the input/output circuit outputs read data on the data line to the I/O pad according to an instruction from the control circuit at the read operation time.

The control circuit receives a control signal input from the exterior of the memory chip and controls the core control drive portion, address circuit, high-voltage generation circuit and input/output circuit. Further, it controls local pumps (SWVPP or SWVPASS) and level shifters (LSTP or LSHVX) of the CG driver 25, SGD driver 26, SGS driver 27, VBST driver 28, VCGSEL driver 29 and VRDEC driver 30, and the VSG bias circuit 31.

When write data is written in a cell transistor, the data is referred to as held data and when the held data is read from the cell transistor, the held data is referred to as read data.

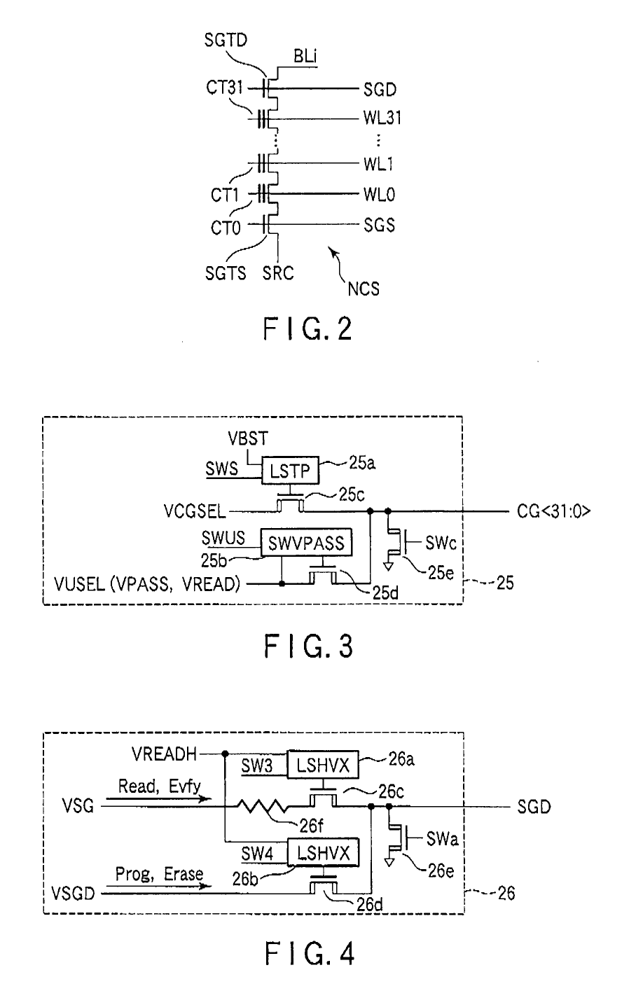

FIG. 2 shows an example of the configuration of the memory cell array 11. In this embodiment, a NAND cell string (NAND string) NCS is configured by, for example, 32 (m) serially-connected memory cell transistors CT (CT<31:0>) and select transistors SGTD, SGTS connected to the ends of the NAND cell string. The NAND cell string NCS is a constituent unit of the memory cell array 11. Each of the memory cell transistors CT is configured by a MOS transistor with a double-gate structure comprising a control gate electrode and floating gate electrode. The word lines WL (WL<31:0>) are connected respective control gate electrodes of memory cell transistors CT.

Select transistor SGTD arranged on one end side of each NAND cell string NCS is connected to a corresponding one of the bit lines BLi. A select signal line SGD is commonly connected to the gate electrodes of select transistors SGTD. Select transistors SGTS arranged on the other end sides of the respective NAND cell strings NCS are commonly connected to a cell source line SRC. A select signal line SGS is commonly connected to the gate electrodes of select transistors SGTS. The word lines WL and select signal lines SGD, SGS are respectively connected to row decoders in the row decoder portion 21. The bit lines BLi are respectively connected to the sense amplifiers S/A. Each block (one unit) BLKn is configured by j NAND cell strings NCS utilizing the same word lines WL and same select signal lines SGD, SGS.

That is, n blocks are provided in the memory cell array 11. Each block BLKn comprises j NAND cell strings NCS connected to respective bit lines BLi. The j NAND cell strings NCS of each block BLKn utilize the same word lines WL and same select signal lines SGD, SGS.

The data write and erase operations are performed by injecting or extracting electrons to or from the floating gate electrode of a selected memory cell transistor CT by use of an EN tunnel current. Generally, a state with electrons captured in the floating gate electrode is defined as a 0-written state and a state without such electrons is defined as a 1-written (erased) state.

FIG. 3 shows an example of the configuration of the CG driver 25. The CG driver 25 comprises a level shifter (LSTP) 25a, local pump circuit (SWVPASS) 25b and transfer gate transistors 25c, 25d, 25e. Output signals CG<31:0> of the CG driver 25 are commonly input to the row decoder of for corresponding one block BLKn. In a selected block, the transfer gate transistors in corresponding one row decoder are turned on and then the output signals CG<31:0> are supplied to the word lines WL (WL<31:0>). That is, the CG driver 25 applies voltage VCGSEL from the VCGSEL driver 29 to the selected word line(s) WL and applies voltage VUSEL (voltage VPASS or VREAD) from the high-voltage generation circuit to the unselected word line(s) WL other than the selected word line(s). In an unselected block, since the transfer gate transistors in corresponding row decoders are turned off, the output signals CG<31:0> are not supplied to the word lines WL (WL<31:0>). Note that a clock signal CLK is omitted in the drawing in this example.

FIG. 4 shows a configuration example of the SGD driver 26. The SGD driver 26 comprises level shifters (LSHVX) 26a, 26b, transfer gate transistors 26c, 26d, 26e and resistor 26f. The SGD driver 26 applies select gate voltage VSG from the VSG bias circuit 31 to select transistor SGTD at the read operation time and erase verify time and applies voltage VSGD from the high-voltage generation circuit to select transistor SGTD at the program operation time and erase operation time.

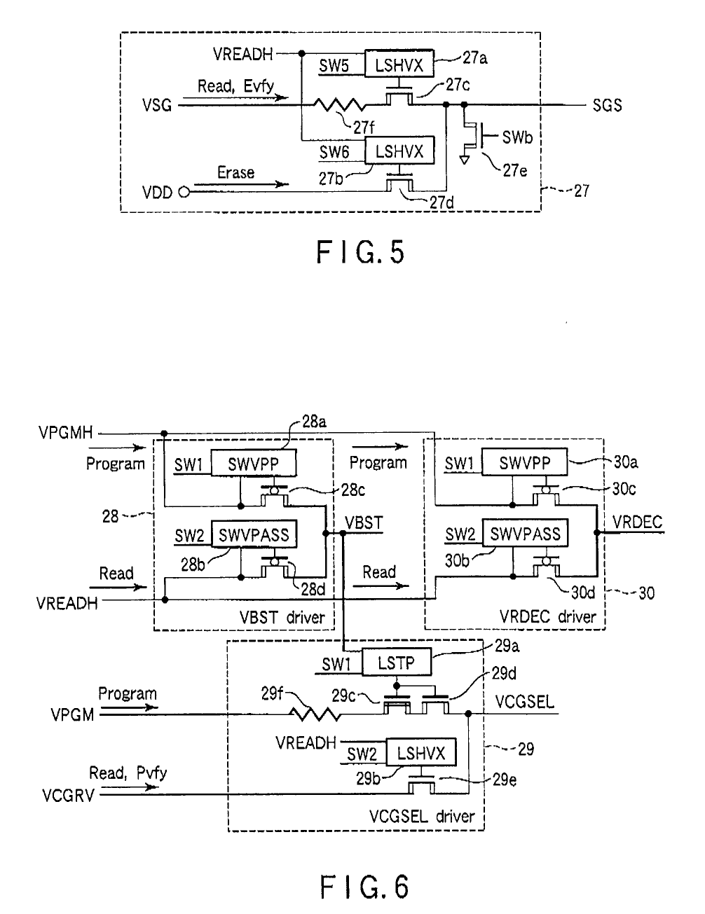

FIG. 5 shows a configuration example of the SGS driver 27. The SGS driver 27 comprises level shifters (LSHVX) 27a, 27b, transfer gate transistors 27c, 27d, 27e and resistor 27f. The SGS driver 27 applies select gate voltage VSG from the VSG bias circuit 31 to select transistor SGTS at the read operation time and erase verify time and applies voltage VDD to select transistor SGTS at the erase operation time.

FIG. 6 shows configurations examples of the VBST driver 28, VCGSEL driver 29 and VRDEC driver 30.

The VBST driver 28 comprises a local pump circuit (SWVPP) 28a, local pump circuit (SWVPASS) 28b and transfer gate transistors 28c, 28d. The VBST driver 28 outputs voltage VPGMH from the high-voltage generation circuit as voltage VBST at the program time and outputs voltage VREADH from the high-voltage generation circuit as voltage VBST at the read time. Output voltage VBST is sufficiently high to transfer voltage VCGSEL and supplied to the level shifters (LSTP) 25a, 29a of the CG driver 25 and VCGSEL driver 29.

The VCGSEL driver 29 comprises a level shifter (LSTP) 29a, level shifter (LSHVX) 29b, transfer gate transistors 29c, 29d, 29e and resistor 29f. The VCGSEL driver 29 outputs program voltage VPGM from the high-voltage generation circuit as voltage VCGSEL at the program time and outputs voltage VCGRV from the high-voltage generation circuit as voltage VCGSEL at the read time. Output voltage VCGSEL is applied to selected word line(s) WL as described before.

The VRDEC driver 30 comprises a local pump circuit (SWVPP) 30a, local pump circuit (SWVPASS) 30b and transfer gate transistors 30c, 30d. The VRDEC driver 30 outputs program voltage VPGMH from the high-voltage generation circuit as voltage VRDEC at the program time and outputs voltage VREADH from the high-voltage generation circuit as voltage VRDEC at the read time. Output voltage VRDEC is supplied to the row decoder portion 21.

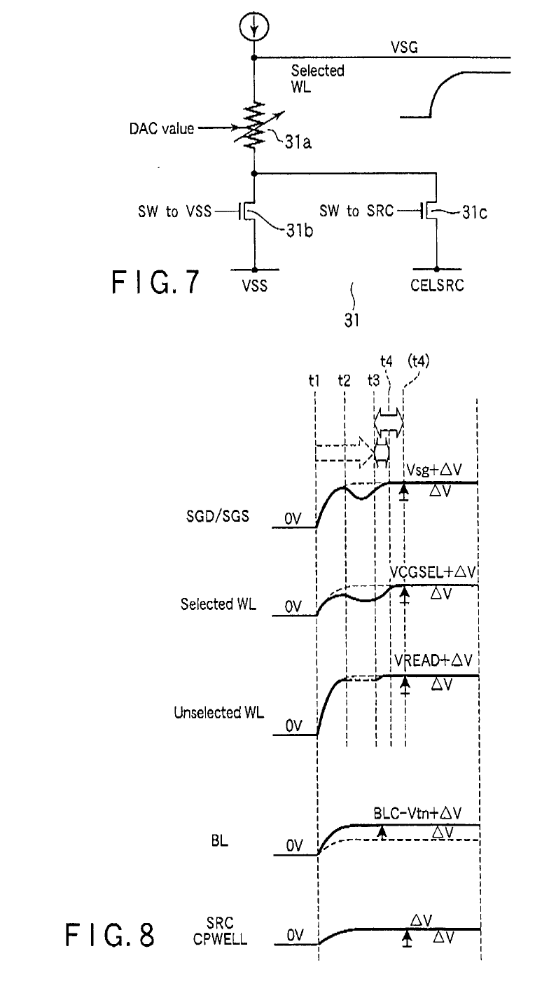

FIG. 7 shows a configuration example of the VSG bias circuit 31. The VSG bias circuit 31 generates select gate voltage VSG. Select gate voltage VSG generated by the VSG bias circuit 31 is finally supplied to select transistors SGTD, SGTS of the memory cell array 11 via the SGD driver 26 and SGS driver 27, respectively.

For example, a voltage (select gate voltage Vsg) of approximately 4 V is simultaneously applied to select transistors SGTD, SGTS as select gate voltage VSG at the positive-threshold cell read (positive potential read or positive level read) time by controlling a variable resistor 31a according to a DAC value from the control circuit (the source node is set at voltage VSS). On the other hand, for example, a select gate voltage of approximately 5 V (voltage (Vsg+ΔV) obtained by adding voltage ΔV biased to the cell source line SRC to select gate voltage Vsg at the positive-threshold cell read time) is finally applied to select transistors SGTD, SGTS as select gate voltage VSG at the negative-threshold cell read time.

Switching transistors 31b, 31c controlled by, for example, the control circuit are provided in the VSG bias circuit 31. In this embodiment, the VSG bias circuit 31 is configured to generate select gate voltage VSG having actual cell source line voltage CELSRC added thereto as a bias voltage (ΔV) by switching the source node voltage to cell source line voltage CELSRC by means of the switching transistors 31b, 31c. That is, it is considered that cell source line voltage CELSRC may have the temperature dependency in order to cancel the temperature dependency of the cell transistor CT in the negative-threshold cell read operation. According to the VSG bias circuit 31, it is possible for select gate voltage VSG to automatically follow cell source line voltage CELSRC having the temperature dependency.

Next, the operation of the above configuration at the negative-threshold cell read time is explained.

FIG. 8 is a timing chart in an example in which unselected word line(s) WL are set in a floating state at the negative-threshold cell read time. That is, in the negative-threshold cell read operation, the unselected word line(s) WL are kept in the floating state for a period (a period of t2-t3) until read voltage (VREAD+ΔV) obtained by adding voltage ΔV equal to voltage biased to the cell source line SRC and cell well line CPWELL to voltage VREAD is applied thereto. Read voltage (VCGSEL+Δv) obtained by adding voltage ΔV biased to the cell source line SRC and cell well line CPWELL to voltage VCGSEL is applied to the selected word line(s) WL from the first timing (time t1). Thus, all unselected word line(s) WL other than the selected word line(s) WL in a NAND cell string NCS, which are set to the highest voltage among the internal nodes of the memory cell array 11 at the negative-threshold cell read time, are kept in the floating state for a period (for example, for a period of t2-t3) until the selected word line voltage is boosted from the start (time t1) of charging of the cell source line SRC and cell well line CPWELL. Therefore, since the potentials of the unselected word line(s) WL can be boosted by capacitive coupling with the cell well line CPWELL, a period (period (t3-t4)) required for boosting the potentials of the unselected word line(s) WL can be reduced. As a result, the negative-threshold cell read operation can be performed at higher speed irrespective of a variation (overshoot) of voltages VSG of select signal lines SGD, SGS due to coupling noise associated with the cell well line CPWELL.

Further, a potential difference (WL-CPWELL) between the word line WL and the cell well line CPWELL can also be reduced and the gate stress of the memory cell transistor CT can also be alleviated.

Voltage VREAD and voltage ΔV for biasing for the unselected word line(s) WL in the NAND cell string NCS may be set to the same value or different values.

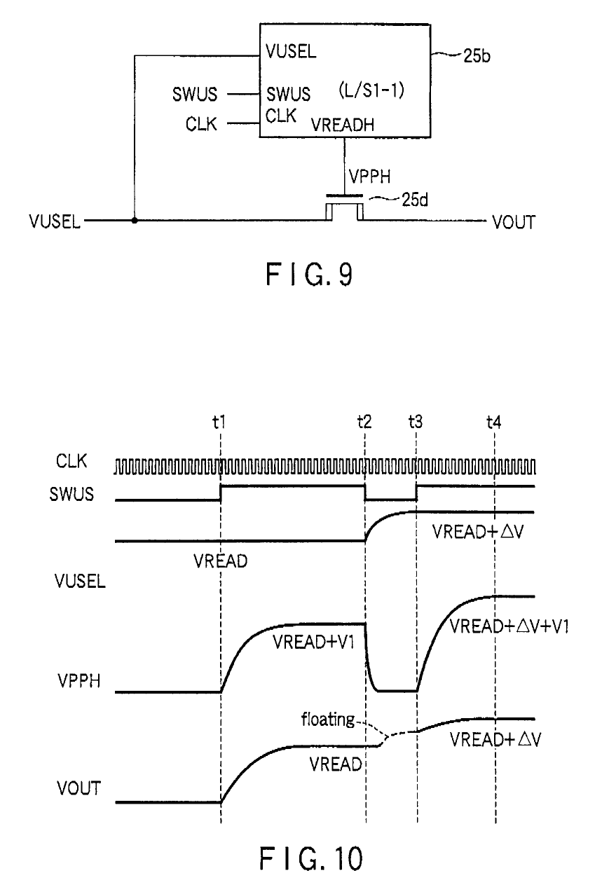

FIG. 9 shows a circuit configuration example to set the unselected word line(s) in the floating state at the negative-threshold cell read operation time. In this embodiment, for example, a case wherein a local pump circuit L/S1-1 is used is shown. That is, an example in which the local pump circuit (SWVPASS) 25b of the CG driver 25 is configured by using the local pump circuit L/S1-1 is shown. Although not shown in the drawing, the local pump circuit (SWVPASS) 28b of the VBST driver 28 and the local pump circuit (SWVPASS) 30b of the VRDEC driver 30 are also configured by using the local pump circuit L/S1-1.

In the case of this embodiment, for example, as shown in FIG. 10, the unselected word line(s) WL are set in the floating state by setting gate voltage VPPH of the transfer gate transistor 25d to 0 V for a period (period of t2 to t3) in which read voltage VUSEL of the unselected word line(s) WL is changed from voltage VREAD to voltage (VREAD+ΔV) at the negative-threshold cell read time.

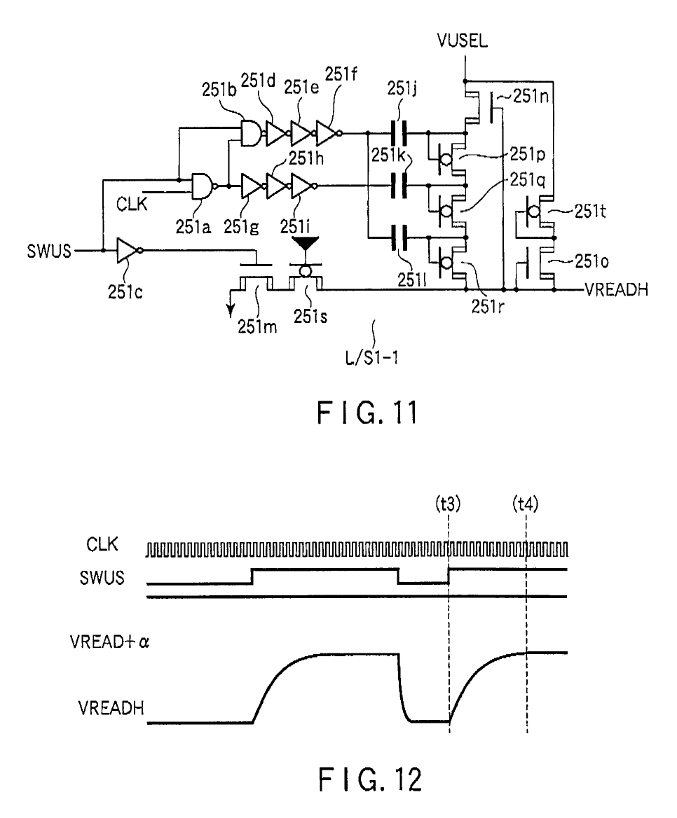

FIG. 11 shows an example of the configuration of the local pump circuit L/S1-1. The local pump circuit L/S1-1 comprises NAND circuits 251a, 251b, inverter circuits 251c to 251i, capacitors 251j to 251l, nMQSFETs 251m to 251o and pMOSFETs 251p to 251t. For example, as shown in FIG. 12, the local pump circuit L/S1-1 shifts the level of a logic input level SWUS (ENB 1/0) to amplify its voltage to voltage (VREAD+α/0 V), which is obtained by boosting read voltage VUSEL, so as to output voltage VREADH (VPPH).

According to this embodiment, the unselected word line(s) WL are set in the floating state by means of the local pump circuit L/S1-1 for a period (t2 to t3) in which the word line voltage is boosted at the negative-threshold cell read time. Thus, a time (t3-t4) required for boosting the potential of the word line WL can be reduced. Therefore, the speed of the negative-threshold cell read operation can be accelerated (i.e., the read time can be reduced). Further, the verify operation can also be accelerated by increasing the read operation speed and, as a result, the program operation, which requires a verify operation, can be performed at higher speed.

### Embodiment 2

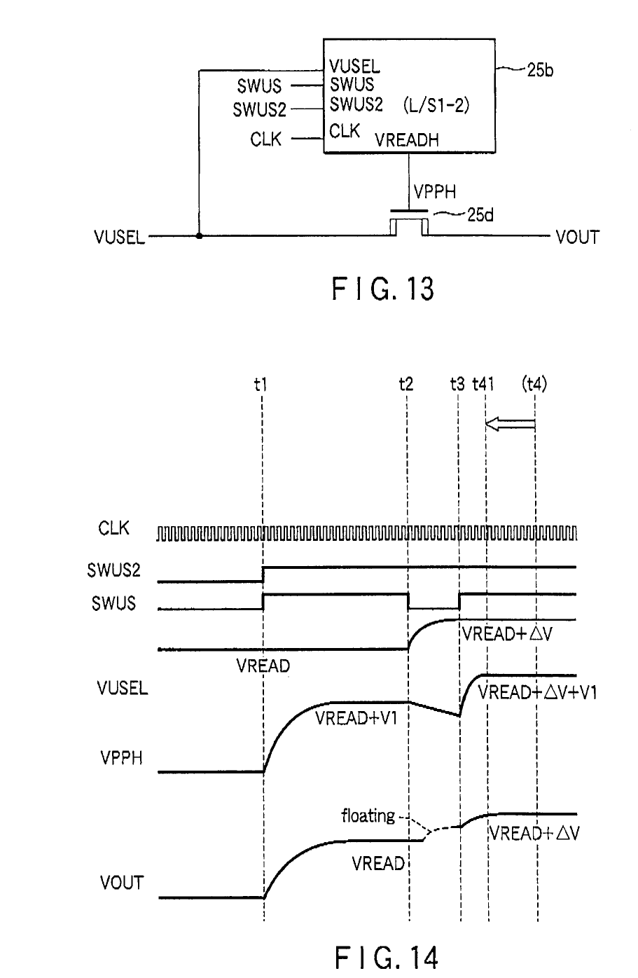

FIG. 13 shows a circuit configuration example for setting unselected word line(s) WL into a floating state at the negative-threshold cell read time according to an embodiment 2 of this invention. The embodiment relates to an example in which the local pump circuit (SWVPASS) 25b of the CG driver 25 is configured by using a local pump circuit L/S1-2 in the nonvolatile semiconductor memory device (NAND flash memory) with the configuration shown in the embodiment 1. Although not shown in the drawing, a local pump circuit 28b of the VBST driver 28 and a local pump circuit 30b of the VRDEC driver 30 are also configured by using the local pump circuit L/S1-2.

In the case of this embodiment, for example, as shown in FIG. 14, the unselected word line(s) WL are set in the floating state by setting gate voltage VPPH of the transfer gate transistor 25d in a floating state for a period (t2 to t3) in which read voltage VUSEL of the unselected word line(s) WL is changed from voltage VREAD to voltage (VREAD+ΔV) at the negative-threshold cell read time. Since the local pump circuit L/S1-2 can reduce voltage by which gate voltage VPPH of the transfer gate transistor 25d is boosted from timing t3, a time required for boosting potential of the word line WL can be reduced (t4>t41).

In the case of the local pump circuit L/S1-2, since a potential difference occurring when gate voltage VPPH of the transfer gate transistor 25d is boosted becomes smaller at timing t3, a time required for boosting potential of the word line WL can be reduced (t4>t41).

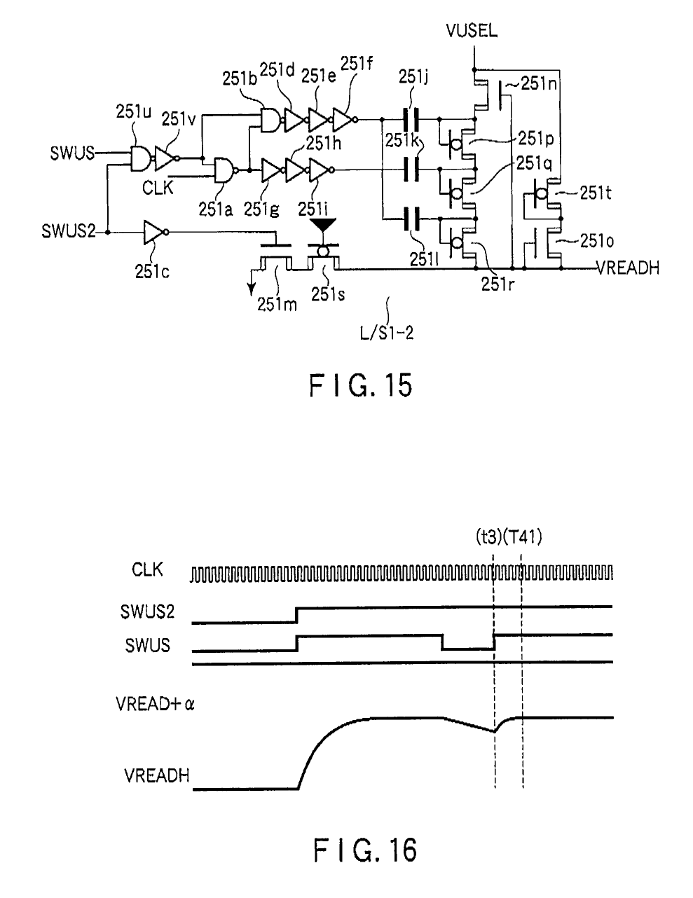

FIG. 15 shows an example of the configuration of the local pump circuit L/S1-2. The local pump circuit L/S1-2 comprises NAND circuits 251a, 251b, 251u, inverter circuits 251c to 251i, 251v, capacitors 251j to 251l, nMOSFETs 251m to 251n and pMOSFETs 251o to 251t. That is, the local pump circuit L/S1-2 has a configuration obtained by adding the NAND circuit 251u and inverter circuit 251v to the local pump circuit L/S1-1. For example, as shown in FIG. 16, the local pump circuit L/S1-2 sets the unselected word line(s) WL in the floating state while voltage VREADH is maintained at boosted potential by interrupting only a clock signal CLK supplied to the capacitors 251j to 251l when voltage VREADH (VPPH) is boosted (only for a period with low logic input level SWUS (ENB) and high logic input level SWUS2 (ENB2)).

According to this embodiment, the unselected word line(s) WL are set in the floating state by the local pump circuit L/S1-2 for a period (t2-t3) in which the word line voltage is boosted at the negative-threshold cell read time. Thus, a time (t3-t4) required for boosting the potential of the word line WL can be reduced. Therefore, the negative-threshold cell read operation can be accelerated. Further, the verify operation speed can be accelerated by increasing the read operation speed and, as a result, the program operation, which requires a verify operation, can be performed at higher speed.

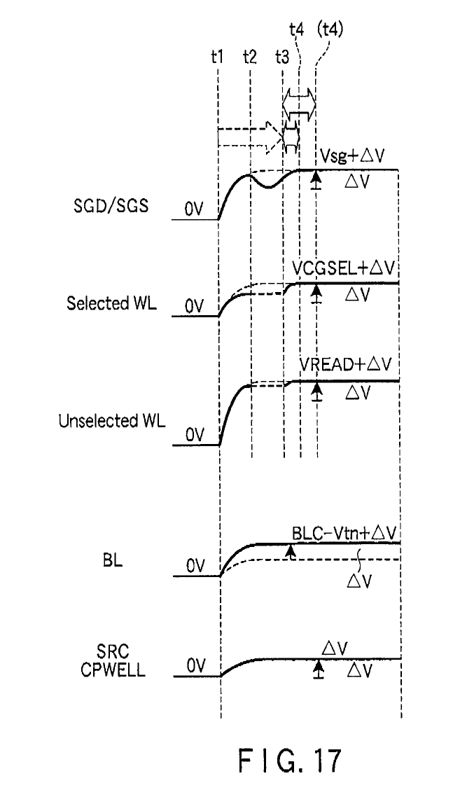

In the embodiment 1 and embodiment 2, an example in which only the unselected word line(s) WL are set in the floating state at the negative-threshold cell read time is explained. However, this invention is not limited to the above example and, for example, as shown in FIG. 17, all of the word lines WL in the NAND cell string NCS that are the internal nodes of the memory cell array 11 may be set in the floating state. That is, in the negative-threshold cell read operation, the unselected word line(s) WL are set in the floating state for a period (a period of t2-t3) until they are supplied with the read voltage (VREAD+ΔV) obtained by adding voltage ΔV biased to the cell source line SRC and cell well line CPWELL to voltage VREAD. The selected word line(s) WL are set in the floating state for a period (a period of t2-t3) until they are supplied with the read voltage (VCGSEL+ΔV) obtained by adding voltage ΔV biased to the cell source line SRC and cell well line CPWELL to voltage VCGSEL. Thus, all of the word lines WL including the selected word line(s) WL and unselected word line(s) WL are set in the floating state at the negative-threshold cell read time for a period (for example, a period of t2-t3) until the word line voltage is boosted from start of charging (time t1) of the cell source line SRC and cell well line CPWELL. Therefore, since the potentials of all of the word lines WL can be boosted by the capacitive coupling thereof with the cell well line CPWELL, a time (a period of t3-t4) required for boosting the potentials of the word lines WL later can be reduced. As a result, the negative-threshold cell read operation can be accelerated irrespective of a variation (overshoot) in voltage VSG of select signal lines SGD, SGS due to coupling noise associated with the cell well line CPWELL.

Further, a potential difference (WL-CPWELL) between the word line WL and the cell well line CPWELL can be reduced and the gate stress of the memory cell transistor CT can also be alleviated.

### Embodiment 3

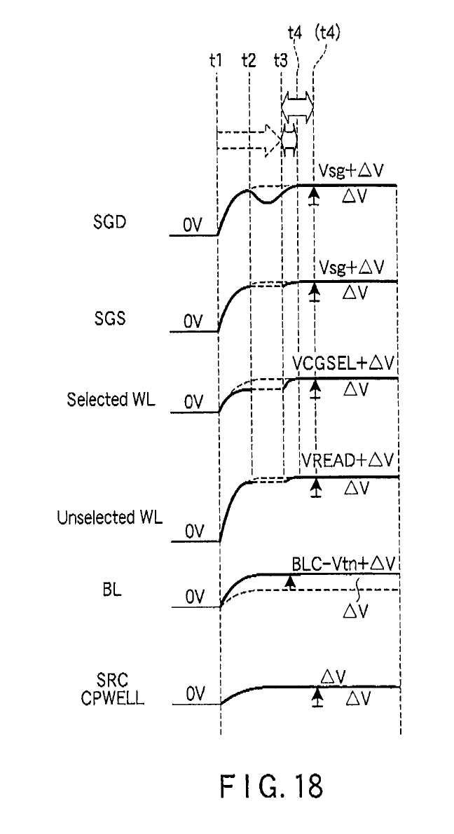

FIG. 18 is a timing chart for illustrating an example in which all of word lines and one of select signal lines SGD, SGS (in this example, select signal line SGS) are set in a floating state at the negative-threshold cell read time according to an embodiment 3 of this invention. That is, in the negative-threshold cell read operation, the unselected word line(s) WL are set in the floating state for a period (a period of t2-t3) until they are supplied with the read voltage (VREAD+ΔV) obtained by adding voltage ΔV biased to the cell source line SRC and cell well line CPWELL to voltage VREAD. The selected word line(s) WL are set in the floating state for a period (a period of t2-t3) until they are supplied with the read voltage (VCGSEL+ΔV) obtained by adding voltage ΔV biased to the cell source line SRC and cell well line CPWELL to voltage VCGSEL. Further, select signal line SGS is set in the floating state for a period (a period of t2-t3) until it is supplied with the read voltage (Vsg+ΔV) obtained by adding voltage ΔV biased to the cell source line SRC and cell well line CPWELL to voltage Vsg. Select signal line SGD is supplied with the read voltage (Vsg+ΔV) obtained by adding voltage ΔV biased to the cell source line SRC and cell well line CPWELL to voltage Vsg from the beginning (time t1). Thus, all of the word lines WL and select signal line SGS are set in the floating state at the negative-threshold cell read time for a period (for example, a period of t2-t3) until the word line voltage is boosted from start of charging (time t1) of the cell source line SRC and cell well line CPWELL. Therefore, since the potentials of all of the word lines WL can be boosted by the capacitive coupling thereof with the cell well line CPWELL, a time (a period of t3-t4) required for boosting the potentials of the word lines WL later can be reduced. As a result, the negative-threshold cell read operation can be accelerated irrespective of a variation (overshoot) in voltage VSG of select signal lines SGD, SGS due to coupling noise associated with the cell well line CPWELL.

Further, a potential difference (WL-CPWELL) between the word line WL and the cell well line CPWELL can be reduced and the gate stress of the memory cell transistor CT can also be alleviated.

Voltage VREAD and voltage ΔV for biasing for the unselected word line(s) WL in the NAND cell string NCS may be set to the same value or different values.

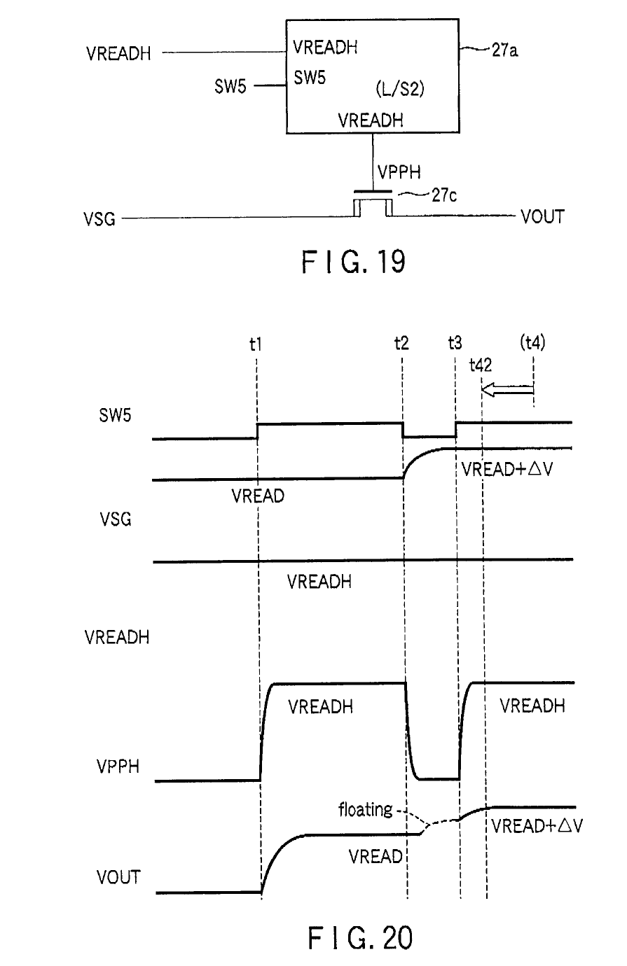

FIG. 19 shows a circuit configuration example for setting all of word lines and one select signal line SGS into the floating state at the negative-threshold cell read operation time. In this embodiment, a case wherein a level shifter L/S2 is used is explained. That is, this embodiment relates to an example in which a level shifter (LSHVX) 27a of an SGS driver 27 is configured by using the level shifter L/S2. Although not shown in the drawing, a level shifter (LSHVX) 29b of a VCGSEL driver 29 is also configured by using the level shifter L/S2. Further, a local pump circuit 25b of a CG driver 25, a local pump circuit 28b of a VBST driver 28 and a local pump circuit 30b of a VRDEC driver 30 are configured by using a local pump circuit L/S1-1 or L/S1-2.

In the case of this example, for example, as shown in FIG. 20, select signal line SGS is set in the floating state by setting gate voltage VPPH of a transfer gate transistor 27c to 0 V for a period (a period (t2 to t3)) in which voltage VSG of select signal line SGD connected to a select transistor SGTD is changed from voltage VREAD to voltage (VREAD+ΔV) at the negative-threshold cell read time.

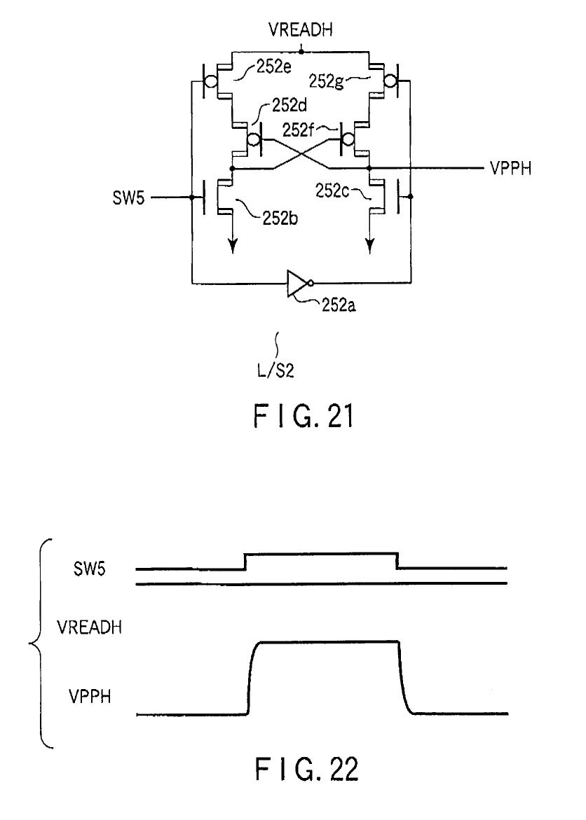

FIG. 21 shows an example of the configuration of the level shifter L/S2. The level shifter L/S2 comprises an inverter circuit 252a, nMOSFETs 252b, 252c and pMOSFETs 252d to 252g. For example, as shown in FIG. 22, the level shifter L/S2 outputs voltage VREADH that is already boosted and is higher than voltage VSG instead of a voltage obtained by boosting voltage VSG as gate voltage VPPH without using a clock signal CLK.

According to this embodiment, charging/discharging gate voltage VPPH can be accelerated by use of a boosted voltage (voltage VREADH) in comparison with a case wherein a local pump circuit is used. Therefore, this can reduce a time (t3-t4) required for boosting the potentials of the word lines WL further in conjunction with setting all of word lines and one select signal line SGS in the floating state for a period (t2-t3) required for the word line voltage to be boosted at the negative-threshold cell read time. Thus, the negative-threshold cell read operation can be accelerated. Further, the verify operation speed can be increased by increasing the read operation speed and, as a result, the program operation, which requires a verify operation, can be performed at higher speed.

In the embodiment 3 described above, an example in which only select signal line SGS is set in the floating state is explained by taking the cutoff characteristics of select transistors SGTD, SGTS into consideration. However, this embodiment is not limited to this case and the same effect can be attained by setting all of the word lines WL and select signal line SGD in the floating state, for example.

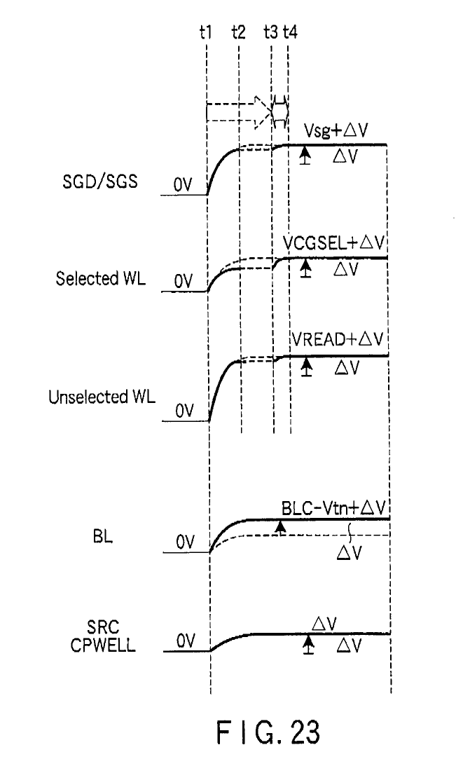

Further, this embodiment is not limited to a case wherein only one of select signal lines SGD, SGS is used, and as shown in FIG. 23, for example, all of the word lines WL and both of select signal lines SGD, SGS may be set in the floating state. That is, in the negative-threshold cell read operation, the unselected word line(s) WL are set in the floating state for a period (a period of t2-t3) until they are supplied with the read voltage (VREAD+ΔV) obtained by adding voltage ΔV biased to the cell source line SRC and cell well line CPWELL to voltage VREAD. The selected word line(s) WL are set in the floating state for a period (a period of t2-t3) until they are supplied with the read voltage (VCGSEL+ΔV) obtained by adding voltage ΔV biased to the cell source line SRC and cell well line CPWELL to voltage VCGSEL. Further, select signal lines SGS, SGD are set in the floating state for a period (a period of t2-t3) until they are supplied with the read voltage (Vsg+ΔV) obtained by adding voltage ΔV biased to the cell source line SRC and cell well line CPWELL to voltage Vsg. Thus, all of the word lines WL and both of select signal lines SGD, SGS are set in the floating state at the negative-threshold cell read time for a period (for example, a period of t2-t3) until the word line voltage is boosted from start of charging (time t1) of the cell source line SRC and cell well line CPWELL. Therefore, since the potentials of all of the word lines WL can be boosted by the capacitive coupling thereof with the cell well line CPWELL, a time (a period of t3-t4) required for boosting the potentials of the word lines WL later can be reduced. As a result, the negative-threshold cell read operation can be accelerated irrespective of a variation (overshoot) in voltage VSG of select signal lines SGD, SGS due to coupling noise associated with the cell well line CPWELL.

Further, a potential difference (WL-CPWELL) between the word line WL and the cell well line CPWELL can be reduced and the gate stress of the memory cell transistor CT can also be alleviated.

In this embodiment, it is not always necessary to set the selected word line(s) in the floating state.

As described above, a design is made to reduce the time required for boosting the potentials of the word lines WL at the negative-threshold cell read time. That is, at least the unselected word line(s) WL are set in the floating state in a period until the word line voltage is boosted. As a result, the potentials of the unselected word line(s) WL can be boosted by the Capacitive coupling with the cell well line CPWELL. This makes it possible to reduce the time required for boosting the potentials of the unselected word line(s) WL, which require a charging time longer than that of the selected word line(s) WL because voltage thereof needs to be boosted to be higher than that of the selected word line(s) WL. As a result, the negative-threshold cell read operation and program operation can be accelerated without setting the selected word line(s) WL in the floating state.

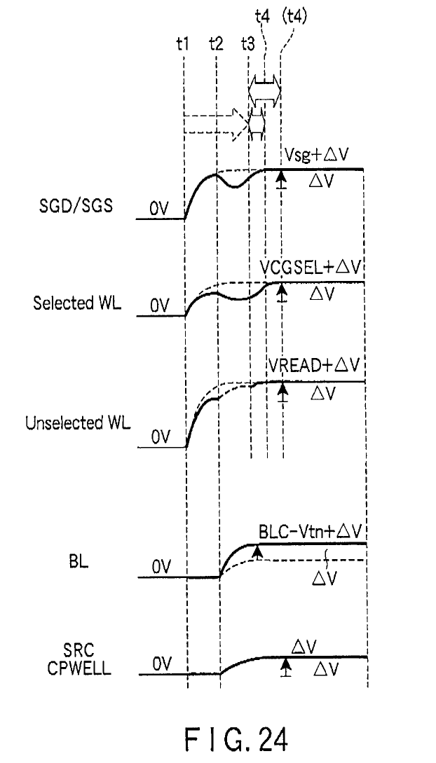

In each of the above embodiments, an example in which the charging of the bit lines BL, cell source line SRC and cell well line CPWELL are started when the rising of the word lines WL and select signal lines SGD, SGS are started (time t1) is explained. However, embodiments are not limited to this case and, for example, as shown in FIGS. 24 to 27, the same effect can be expected even if boosting of the potentials of the bit lines BL, cell source line SRC and cell well line CPWELL is started different timing when boosting of the word lines WL and select signal lines SGD, SGS is started.

FIG. 24 is a timing chart for illustrating an example in which boosting of the voltage of the bit lines BL, cell source line SRC and cell well line CPWELL is started at t2 instead of t1 in an example where only the unselected word line(s) WL are set in the floating state at the negative-threshold cell read time (refer to FIG. 8). Also in this example, all of the unselected word line(s) WL other than the selected word line(s) WL in the NAND cell string NOS are set in the floating state for a period (for example, for a period of t2-t3) until the word line voltage is boosted from start of charging (time t2) of the cell source line SRC and cell well line CPWELL. Therefore, the time (period t3-t4) required for boosting the potentials of the unselected word line(s) WL later can be reduced. This can accelerate the negative-threshold cell read operation and program operation.

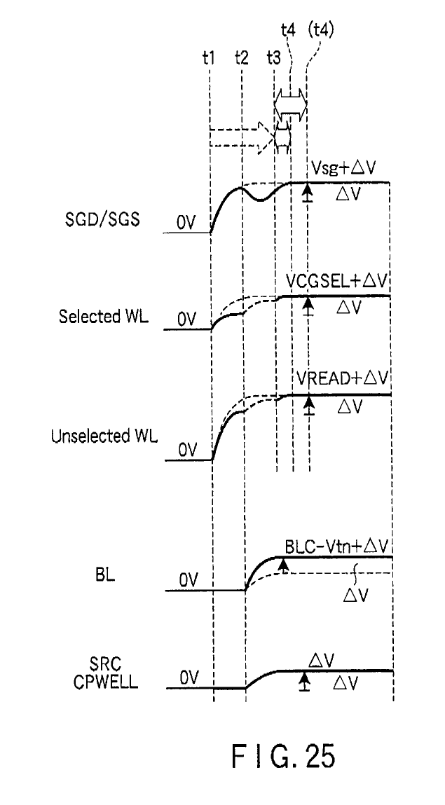

FIG. 25 is a timing chart for illustrating an example in which boosting of the voltage of the bit lines BL, cell source line SRC and cell well line CPWELL is started at t2 instead of t1 in an example where all of the word lines WL are set in the floating state at the negative-threshold cell read time (refer to FIG. 17). Also in this example, all of the word lines WL in the NAND cell string NCS are set in the floating state for a period (for example, for a period of t2-t3) until the word line voltage is boosted from start of charging (time t2) of the cell source line SRC and cell well line CPWELL. Therefore, the time (period (t3-t4)) required for boosting the potentials of the word lines WL later can be reduced. This can accelerate the negative-threshold cell read operation and program operation.

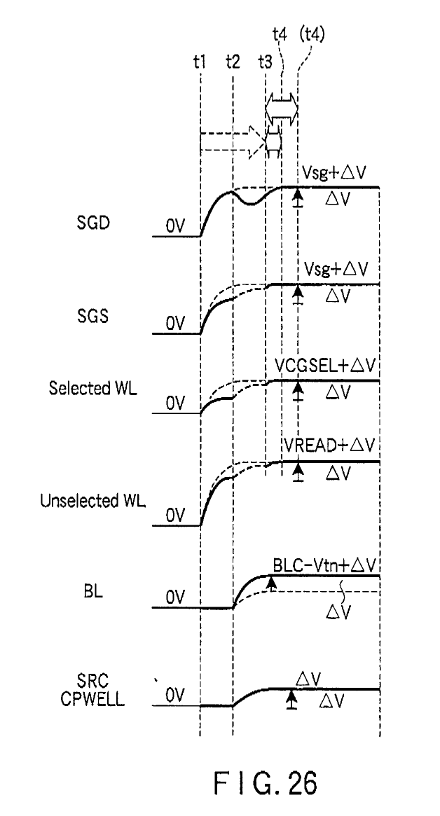

FIG. 26 is a timing chart for illustrating an example in which boosting of the voltage of the bit lines BL, cell source line SRC and cell well line CPWELL is started at t2 instead of t1 in an example where all of the word lines WL and one of the select signal lines (for example, select signal line SGS) are set in the floating state at the negative-threshold cell read time (refer to FIG. 18). Also in this example, all of the word lines WL and one select signal line SGS in the NAND cell string NCS are set in the floating state for a period (for example, for a period of t2-t3) until the word line voltage is boosted from start of charging (time t2) of the cell source line SRC and cell well line CPWELL. Therefore, the time (period (t3-t4)) required for boosting the potentials of the word lines WL later can be reduced. This can accelerate the negative-threshold cell read operation and program operation.

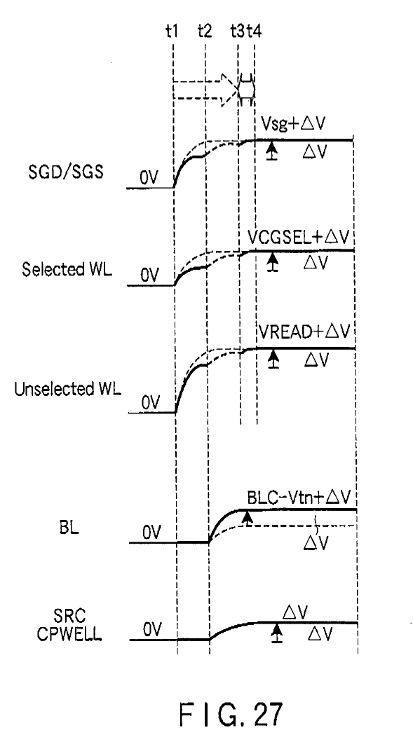

FIG. 27 is a timing chart for illustrating an example in which boosting of the voltage of the bit lines BL, cell source line SRC and cell well line CPWELL is started at t2 instead of t1 in an example where all of the word lines WL and both of select signal lines SGD, SGS are set in the floating state at the negative-threshold cell read time (refer to FIG. 23). Also in this example, all of the word lines WL and both of select signal lines SGD, SGS in the NAND cell string NCS are set in the floating state for a period (for example, for a period of t2-t3) until the word line voltage is boosted from start of charging (time t2) of the cell source line SRC and cell well line CPWELL. Therefore, the time (period (t3-t4)) required for boosting the potentials of the word lines WL later can be reduced. This can accelerate the negative-threshold cell read operation and program operation.

In each example described above, it is not always necessary to set the selected word line(s) in the floating state.

Further, each embodiment is not limited to the NAND flash memory and can be applied to various types of nonvolatile semiconductor memory devices such as a NOR memory in which a negative-threshold cell read operation can be performed.

In addition, this invention is not limited to the above embodiments and can be variously modified without departing from the scope thereof at the embodying stage. Further, inventions at various stages are contained in the above embodiments and various inventions can be extracted by adequately combining a plurality of constituents disclosed. For example, in a case where (at least one of) the problems described above can be solved and (at least one of) the effects described in the item of “the effect of this invention” can be attained even if some constituents among all of the constituents disclosed in the embodiments are eliminated, the configuration obtained by eliminating the above constituents can be extracted as the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device in which a negative-threshold cell read operation is performed by biasing a source line and well line to a positive voltage, comprising:
a first drive circuit that sets at least unselected word line in a floating state at a negative-threshold cell read time.

2. The device according to claim 1, further comprising a second drive circuit which sets at least one select signal line included in a cell string in the floating state.

3. The device according to claim 1, further comprising a second drive circuit which sets all select signal lines included in a cell string in the floating state.

4. The device according to claim 1, wherein the first drive circuit applies 0 V to a gate of a transfer gate transistor connected to the unselected word line when a boosted potential obtained by adding the biased positive voltage to a voltage for negative-threshold cell reading is applied to the unselected word line.

5. The device according to claim 1, wherein the first drive circuit sets a gate of a transfer gate transistor connected to the unselected word line in the floating state when a boosted potential obtained by adding the biased positive voltage to a voltage for negative-threshold cell reading is applied to the unselected word line.

6. The device according to claim 1, wherein the first drive circuit sets all word lines in a cell string including the unselected word line in the floating state.

7. The device according to claim 6, further comprising a second drive circuit which sets at least one select signal line included in a cell string in the floating state.

8. The device according to claim 6, further comprising a second drive circuit which sets all select signal lines included in a cell string in the floating state.

9. The device according to claim 6, wherein the first drive circuit applies 0 V to a gate of a transfer gate transistor connected to the unselected word line when a boosted potential obtained by adding the biased positive voltage to a voltage for negative-threshold cell reading is applied to the unselected word line.

10. The device according to claim 6, wherein the first drive circuit sets a gate of a transfer gate transistor connected to the unselected word line in a floating state when a boosted potential obtained by adding the biased positive voltage to a voltage for negative-threshold cell reading is applied to the unselected word line.

11. A nonvolatile semiconductor memory device comprising:
a memory cell array including cell strings, each cell string being configured by a serial connection of cell transistors and select transistors, the cell transistors configured to store data nonvolatily according to a threshold voltage of corresponding one cell transistor and configured to have a negative threshold voltage;
a driver that biases a source line and well line to a positive voltage;
word lines connected to the cell transistors respectively, and
a drive circuit configured to apply first and second voltages used to read data from the cell transistors to one or more selected word lines and one or more unselected word lines among the word lines, the first and second voltages being set to voltages obtained by adding the positive voltage to the first and second voltages for reading data from the cell transistor having the negative threshold voltage, and the drive circuit setting the one or more unselected word lines in a floating state when data is read from one or more of the cell transistors having the negative threshold voltage.

12. The device according to claim 11, wherein the drive circuit
generates a third voltage used to select one of the cell strings,
applies the third voltage to the select transistors in the selected cell string and
sets a gate of at least one of the select transistors in the selected cell string in the floating state when data is read from one or more of the cell transistors having the negative threshold voltage.

13. The device according to claim 11, wherein the drive circuit
generates a third voltage used to select one of the cell strings,
applies the third voltage to the select transistors in the selected cell string and
sets gates of all of the select transistors in the selected cell string in the floating state when data is read from one or more of the cell transistors having the negative threshold voltage.

14. The device according to claim 11, wherein the drive circuit applies 0 V to a gate of a transfer gate transistor connected to the one or more unselected word lines while the second voltage is being applied to the one or more unselected word lines when data is read from one or more of the cell transistors having the negative threshold voltage.

15. The device according to claim 11, wherein the drive circuit sets a gate of a transfer gate transistor connected to the one or more unselected word lines in the floating state while the second voltage is being applied to the one or more unselected word lines when data is read from one or more of the cell transistors having the negative threshold voltage.

16. The device according to claim 11, wherein the drive circuit sets all of the word lines in a selected one of the cell strings in the floating state.

17. The device according to claim 16, wherein the drive circuit
generates a third voltage used to select one of the cell strings,
applies the third voltage to the select transistors in the selected cell string and
sets a gate of at least one of the select transistors in the selected cell string in the floating state when data is read from one or more of the cell transistors having the negative threshold voltage.

18. The device according to claim 16, wherein the drive circuit
generates a third voltage used to select one of the cell strings,
applies the third voltage to the select transistors in the selected cell string and
sets gates of all of the select transistors in the selected cell string in the floating state when data is read from one or more of the cell transistors having the negative threshold voltage.

19. The device according to claim 16, wherein the drive circuit applies 0 V to a gate of a transfer gate transistor connected to the one or more unselected word lines while the second voltage is being applied to the one or more unselected word lines when data is read from one or more of the cell transistors having the negative threshold voltage.

20. The device according to claim 16, wherein the drive circuit sets a gate of a transfer gate transistor connected to the one or more unselected word lines in the floating state while the second voltage is being applied to the one or more unselected word lines when data is read from one or more of the cell transistors having the negative threshold voltage.
